(19) United States
(12) Patent Application Publication
(10) Pub. No.: US 2008/0000513 A1
(43) Pub. Date: Jan. 3, 2008

(54) Apparatus and method for lighting a collapsible structure

(76) Inventors: Lee Pil Yul, Seoul City (KR); Huang Chang Jiu, Xiamen (CN)

Correspondence Address: PATRICK W. RASCHE;ARMSTRONG TEASDALE LLP, ONE METROPOLITAN SQUARE, SUITE 2600, ST. LOUIS, MO, 63102-2740, US

(21) Appl. No.: 11/731,308

(22) Filed: Mar. 30, 2007

(30) Foreign Application Priority Data
Mar. 30, 2006 (CN) 200620082552.2

(51) Int. Cl. H01L 31/045; H01L 31/042

(52) U.S. Cl. 136/245; 136/244

(57) ABSTRACT

A solar power generator includes a hub defining a passage. A solar apparatus is removably coupled to the hub. The solar apparatus includes a solar panel configured to absorb solar energy from the sun and a power source configured to convert the solar energy absorbed by the solar panel to electrical energy. A load device is removably coupled to the hub. The load device includes a sleeve positioned within the passage and operatively coupling the load device to the power source. The power source is configured to supply electrical energy to the load device.

### CROSS REFERENCE TO RELATED APPLICATIONS

This application claims the benefit of Chinese Patent Application 200620082552.2 entitled “Solar Normal Tent” filed on Mar. 30, 2006, which is hereby incorporated by reference in its entirety.

### BACKGROUND OF THE INVENTION

This invention relates generally to collapsible structures, such as tents and gazebos, and, more particularly, to collapsible structures having an apparatus for converting solar energy to electrical energy and providing that energy to an interior space defined by the collapsible structure.

Camping and social activities are becoming increasingly popular. With people's current living standards improving, so are the demands for simplified and user-friendly camping and/or social activity structures. For example, tents are becoming a favored necessity for camping activities. To provide more enjoyment for the camper, electric home appliances and/or lighting devices provide the modern conveniences that the camper is accustom to in his or her lifestyle. In many camping situations, batteries are the only available power source for these conveniences. However, many conventional batteries supply only a limited amount of electric power.

### BRIEF DESCRIPTION OF THE INVENTION

In one aspect, a solar power generator is provided. The solar power generator includes a hub defining a passage. A solar apparatus is removably coupled to the hub. The solar apparatus includes a solar panel configured to absorb solar energy from the sun and a power source configured to convert the solar energy absorbed by the solar panel to electrical energy. A load device is removably coupled to the hub. The load device includes a sleeve positioned within the passage and operatively coupling the load device to the power source. The power source is configured to supply electrical energy to the load device.

In another aspect, a collapsible structure is provided. The collapsible structure includes a hub defining a passage extending along an axis of the hub. A plurality of frame members each are coupled to the hub and at least partially form a collapsible frame assembly. A solar apparatus is removably coupled to the hub and defines a socket aligned along the axis. The solar apparatus includes a solar panel configured to absorb solar energy from the sun and a power source operatively coupled to the solar panel configured to convert the solar energy absorbed by the solar panel to electrical energy. A load device is removably coupled to the hub. The load device includes a sleeve positioned within the passage and electrically coupling the load device to the power source. The power source is configured to supply electrical energy to the load device.

In another aspect, a method for lighting an interior space defined by a collapsible structure is provided. The method includes constructing a collapsible structure including a hub and a plurality of frame members each pivotally coupled to the hub. The plurality of frame members at least partially form a collapsible frame assembly of the collapsible structure. A solar apparatus is removably coupled to the hub. The solar apparatus includes a solar panel configured to absorb solar energy from the sun and a power source operatively coupled to the solar panel and configured to convert the solar energy to electrical energy. A load device is removably coupled to the hub and electrically coupled to the solar apparatus.

### BRIEF DESCRIPTION OF THE DRAWINGS

FIG. 1 is a perspective view an exemplary collapsible structure;

FIG. 2 is a perspective view an exemplary solar power generator coupled to the collapsible structure shown in FIG. 1 with a light source in a collapsed configuration;

FIG. 3 is a perspective exploded view of the solar power generator shown in FIG. 2;

FIG. 4 is a perspective view the solar power generator coupled to the collapsible structure shown in FIG. 1 with the light source in an expanded configuration;

FIG. 5 is a perspective exploded view of the solar power generator shown in FIG. 4;

FIG. 6 is a perspective view of a top portion of a ridge hub;

FIG. 7 is a perspective view of a bottom portion of the ridge hub opposing the top portion shown in FIG. 6;

FIG. 8 is an exploded view an exemplary solar power generator with a light source in a collapsed configuration;

FIG. 9 is a perspective exploded view of a portion of the solar power generator shown in FIG. 8;

FIG. 10 is a perspective view of the solar power generator shown in FIG. 9;

FIG. 11 is a perspective view of the solar power generator shown in FIG. 9 with the light source in an expanded configuration;

FIG. 12 is a perspective exploded view of the solar power generator shown in FIG. 11;

FIG. 13 is a perspective view of a bottom portion of a solar apparatus;

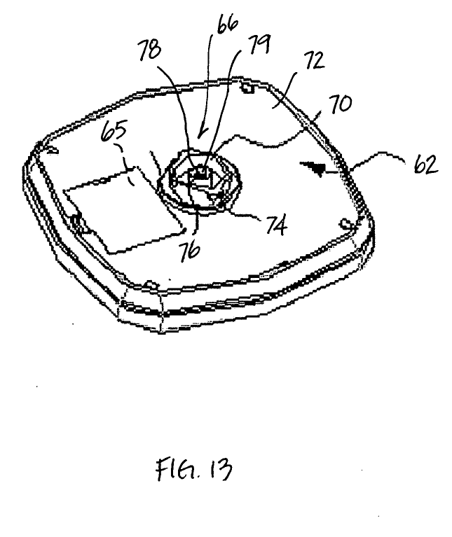

FIG. 14 is a perspective view of a top portion of the solar apparatus opposing the bottom portion shown in FIG. 13;

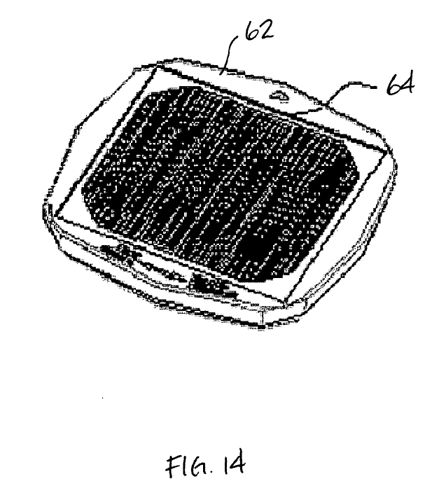

FIG. 15 is a plan view of an alternative exemplary load device suitable for use with the solar power generator shown in FIG. 2;

FIG. 16 is a plan view of an alternative exemplary load device suitable for use with the solar power generator shown in FIG. 2; and

FIG. 17 is a perspective view an alternative exemplary collapsible structure.

### DETAILED DESCRIPTION OF THE INVENTION

The present invention provides a collapsible structure, such as a tent, a canopy or a gazebo, including an apparatus for facilitating converting solar energy to electrical energy for supplying electric power to a load device, such as an appliance and/or a lighting device for lighting an interior space defined by the collapsible structure and/or an exterior area about the collapsible structure. In one embodiment, the apparatus utilizes photovoltaic principles to generate electrical energy from solar power obtained from the sun.

The present invention is described below in reference to its application in connection with and operation of an apparatus and method for facilitating lighting an interior space defined by a collapsible structure, such as a tent, a canopy or a gazebo. However, it will be apparent to those skilled in the art and guided by the teachings herein provided that the invention is likewise applicable to any suitable collapsible and/or permanent structure for facilitating providing electric power to any suitable load device including, without limitation, a household appliance and/or a light source.

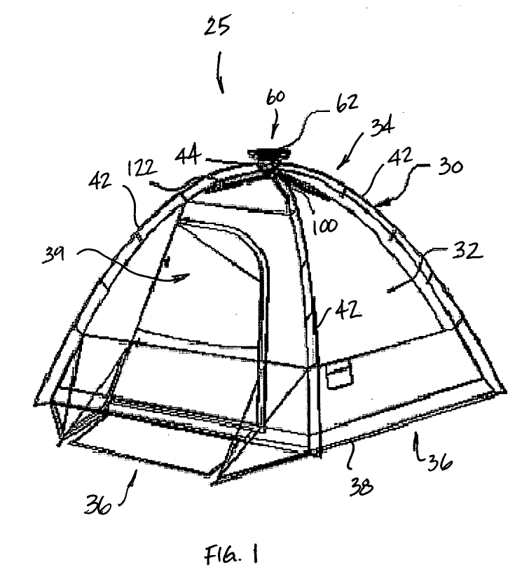

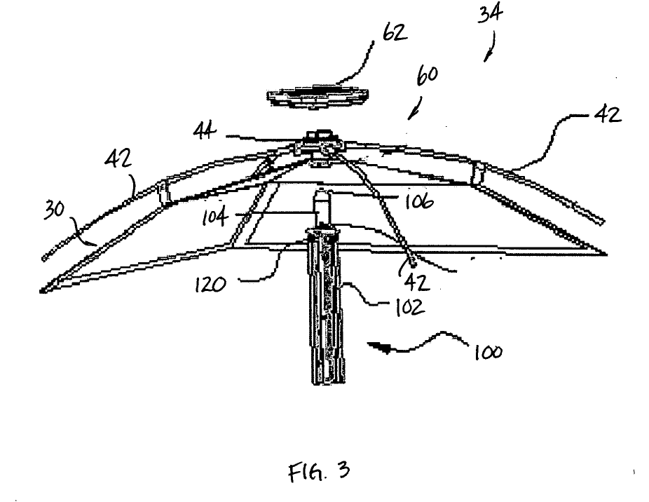

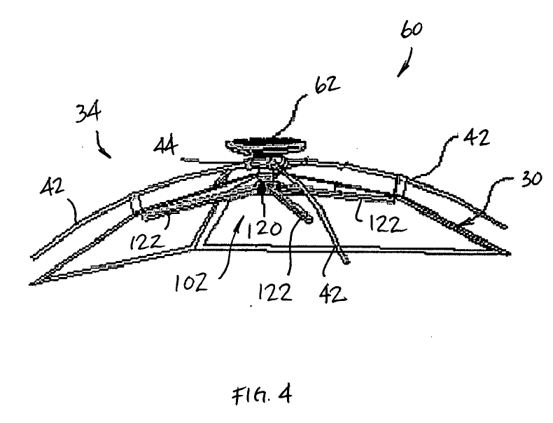

FIGS. 1-4 show an exemplary collapsible structure 25. In this embodiment, collapsible structure 25 is a tent 30 that includes a main tent structure 32 formed of a suitable fabric material. Tent structure 32 is coupled to a collapsible frame assembly 34 to form a plurality of walls 36. A floor 38 is coupled to each wall 36 to form the collapsible structure and define an interior space 39 therein. Interior space 39 is large enough to comfortably accommodate one or more people. It is apparent to those skilled in the art and guided by the teachings herein provided that tent 30 may include any suitable number of walls having any suitable size and/or shape.

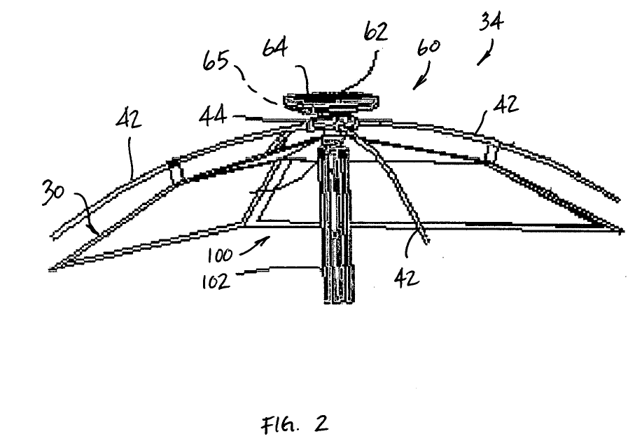

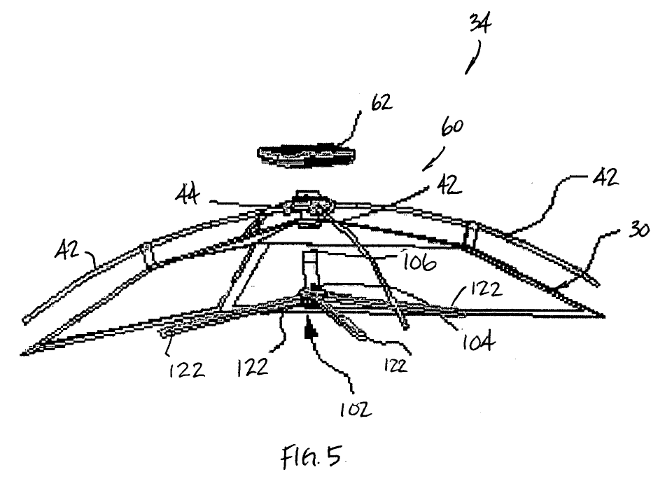

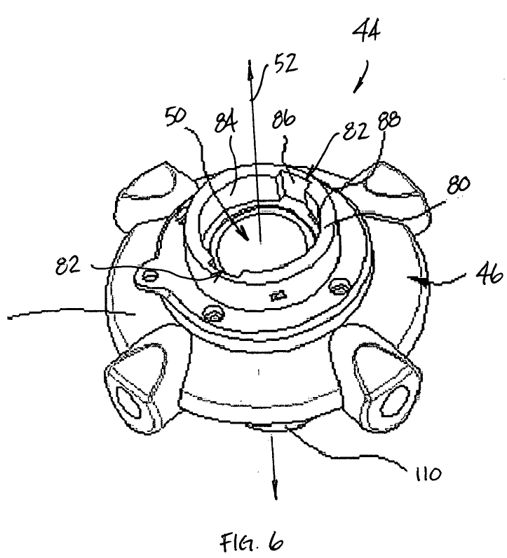

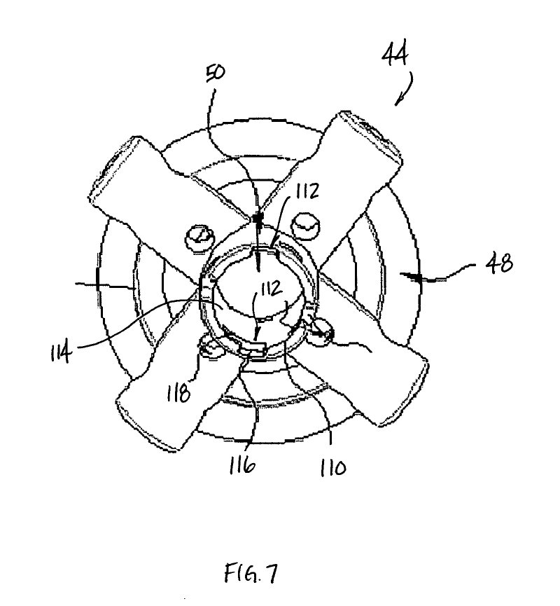

Referring further to FIGS. 2-5, collapsible frame assembly 34 includes a plurality of collapsible poles or frame members 42 coupled to a ridge hub 44. In one embodiment, collapsible frame assembly 34 includes four frame members 42 coupled to ridge hub 44 to at least partially form collapsible frame assembly 34. Ridge hub 44 includes a first or top portion 46, as shown in FIG. 6, that is positioned externally with respect to interior space 39. As shown in FIG. 7, ridge hub 44 also includes a second or bottom portion 48 opposing first portion 46 that is positioned within interior space 39, as described in greater detail below. Ridge hub 44 defines a passage 50 that extends through ridge hub 44 between first portion 46 and second portion 48. In one embodiment, passage 50 coaxially extends along an axis 52 of ridge hub 44.

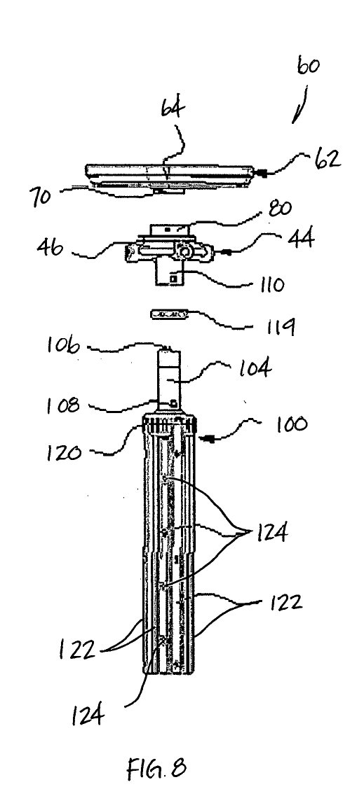

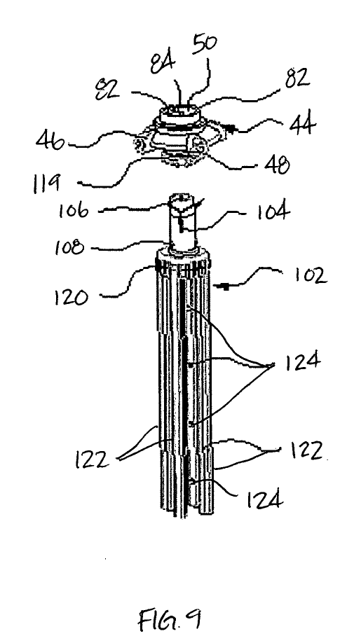

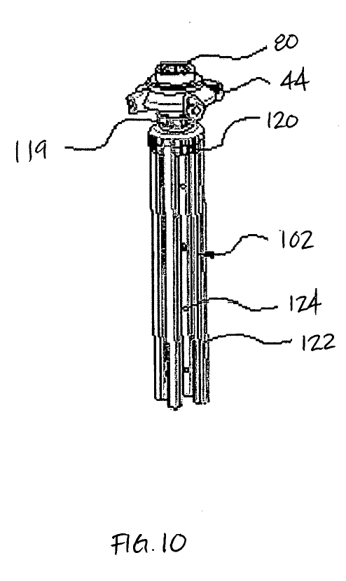

Referring also to FIGS. 8-12, a solar power generator 60 is configured to obtain and/or absorb solar energy and convert the solar energy to electrical energy to provide power to a load device including, without limitation, at least one light source, a fan and/or an appliance. In one embodiment, solar power generator 60 is suitable for use in cooperation with collapsible structure 25 to provide light within interior space 39, for example.

Solar power generator 60 includes a solar apparatus 62 removably coupled to ridge hub 44. Solar apparatus 62 includes a solar panel 64 configured to absorb solar energy from the sun and an electrical power source 65 operatively coupled to solar panel 64. Power source 65 is electrically coupled to solar panel 64 using a suitable conductive wire (not shown). Power source 65 is configured to convert the solar energy absorbed by solar panel 64 to electrical energy to facilitate providing electric power to a load device operatively coupled to solar power generator 60. In one embodiment, power source 65 also includes a storage device, such as a storage battery (not shown), configured to store generated, unused and/or excess electrical energy. In a particular embodiment, power source 65 includes a battery, such as a deep-cycle battery or other suitable battery known to those skilled in the art and guided by the teachings herein provided. The battery is configured to store at least a portion of the generated electrical energy. In one embodiment, the battery is electrically coupled through the conductive wire to a solar power output 66. Solar apparatus 62 also includes a circuit board (not shown) electrically coupled to power source 65. In one embodiment, a plug is electrically coupled to the power source to removably couple the load device to the power source. In a particular embodiment, a photoconductor device is coupled to the circuit board. In an alternative embodiment, power source 65 may be an independent component of solar power generator 60 that is operatively coupled to solar apparatus 62. Alternatively, power source 65 may be integrated with the load device, removably coupled to solar apparatus 60, and operatively coupled to the solar panel 64.

In one embodiment, solar apparatus 62 includes an arcuate or circular locking collar 70 on a bottom surface 72 of solar apparatus 62. In this embodiment, locking collar 70 is configured to rotatably couple to ridge hub 44. Locking collar 70 is rotatable with respect to ridge hub 44 between a first or unlocked position and a second or locked position. In a particular embodiment, locking collar 70 includes one or more projections 74 formed or coupled to a radially outer surface 76 of locking collar 70 to facilitate coupling locking collar 70 to ridge hub 44. A socket 78 is formed on or coupled to bottom surface 72 of solar apparatus 62 to define a power port 79. In one embodiment, socket 78 is positioned within locking collar 70 such that socket 78 and/or power port 79 is coaxial with axis 52 with solar apparatus 62 coupled to ridge hub 44. Solar apparatus 62 includes a conductive wire (not shown) electrically coupling socket 78 to power source 65.

As shown in FIG. 6, ridge hub 44 includes a locking ring 80 on first portion 46 cooperating with locking collar 70 to facilitate removably coupling solar apparatus 62 to ridge hub 44. More specifically, projections 74 formed or coupled to radially outer surface 76 of locking collar 70 are positioned within a corresponding groove 82 defined within a radially inner surface 84 of locking ring 80. Groove 82 includes a recess 86 that transitions into a slot 88 such that corresponding projection 74 is inserted into recess 86. Solar apparatus 62 is then rotated with respect to ridge hub 44 to position projection 74 within slot 88. With projection 74 properly positioned within slot 88, solar apparatus 62 is secured in a locked position to ridge hub 44. It should be apparent to those skilled in the art and guided by the teachings herein provided that locking collar 70 and/or locking ring 80 may form or define any suitable mechanism for removably coupling solar apparatus 62 to ridge hub 44.

Solar power generator 60 also includes a load device 100 removably coupled to ridge hub 44. Light source 102 is electrically coupled to solar apparatus 62 and configured to receive electrical energy produced by solar apparatus 62 for facilitating providing light to interior space 39 defined within tent 30. In one embodiment, load device 100 includes at least one light source 102 electrically coupled to power source 65 such that power source 65 supplies electrical energy to light source 102. Light source 102 includes a sleeve 104 that is positioned within passage 50 to electrically couple light source 102 to solar apparatus 62 and/or power source 65. More specifically, a conducting surface or pin 106 is coupled to a first end of sleeve 104. Conducting pin 106 is positioned within power port 79 to contact socket 78 and electrically couple light source 102 to power source 65.

In one embodiment, light source 102 includes a switch (not shown) that is movable between a first or “on” position configured to supply electrical energy to light source 102 and a second or “off” position configured to prevent energy from being supplied to light source 102.

As shown in FIG. 7, ridge hub 44 includes a second locking ring 110 on second portion 48 opposing first portion 46. Locking ring 110 cooperates with sleeve 104 to facilitate removably coupling load device 100 to ridge hub 44. More specifically, projections 108 formed or coupled to the radially outer surface of sleeve 104 are positioned within a corresponding groove 112 defined within a radially inner surface 114 of second locking ring 110. Groove 112 includes a recess 116 that transitions into a slot 118 such that corresponding projection 108 is inserted into recess 116 and load device 100 is rotated with respect to ridge hub 44 to position projection 108 within slot 118. With projection 108 properly positioned within slot 118, load device 100 is secured in a locked position to ridge hub 44. It should be apparent to those skilled in the art and guided by the teachings herein provided that sleeve 104 and/or second locking ring 110 may form or define any suitable mechanism for removably coupling load device 100 to ridge hub 44.

In one embodiment, a stopper 119 is removably coupled to second portion 48 of ridge hub 44 to position a portion of the fabric of tent structure 32 between second portion 48 and stopper 119 to prevent or limit leakage of moisture into interior space 39, for example. In a particular embodiment, stopper 119 includes projections (not shown) that cooperate with second locking ring 110 to facilitate removably coupling stopper 119 to ridge hub 44. More specifically, projections formed or coupled to the radially inner surface of stopper 119 are positioned within a corresponding groove defined within a radially outer surface of second locking ring 110. The groove includes a recess that transitions into a slot such that the corresponding projection is inserted into recess and stopper 119 is rotated with respect to ridge hub 44 to position the projection within the slot and secure stopper 119 to ridge hub 44. It should be apparent to those skilled in the art and guided by the teachings herein provided that stopper 119 and/or second locking ring 110 may form or define any suitable mechanism for removably coupling stopper 119 to ridge hub 44.

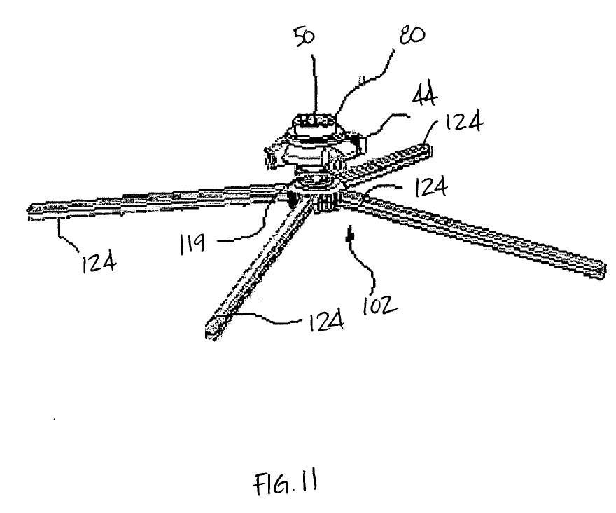

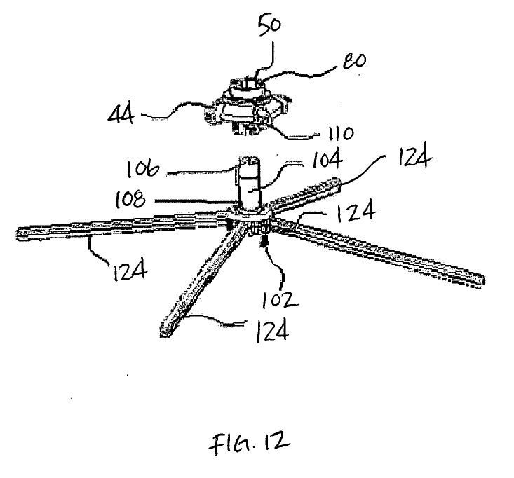

In one embodiment, light source 102 includes a base 120. A plurality of arms 122 are coupled to base 120. In a particular embodiment, each arm 122 is pivotally coupled to base 120 and movable between a collapsed configuration, as shown in FIGS. 8-10, and an extended configuration extending radially outwardly from base 120, as shown in FIGS. 11 and 12, to facilitate providing light throughout interior space 39. In an alternative embodiment, each arm 122 is fixedly coupled to base 120 and extends radially outwardly from base 120. Arms 122 include one or more suitable lights, such as a plurality of LED lights 124, electrically coupled to power source 65. LED lights 124 are configured to emit light to facilitate lighting interior space 92 of collapsible structure 25. It is apparent to those skilled in the art and guided by the teachings herein provided that any suitable number of lights and/or type of electrical lighting devices can be used with solar apparatus 62 of the present invention for facilitating illuminating interior space 39 defined by tent 30. In an alternative embodiment, light source 102 is configured to facilitate lighting an exterior space about collapsible structure 25.

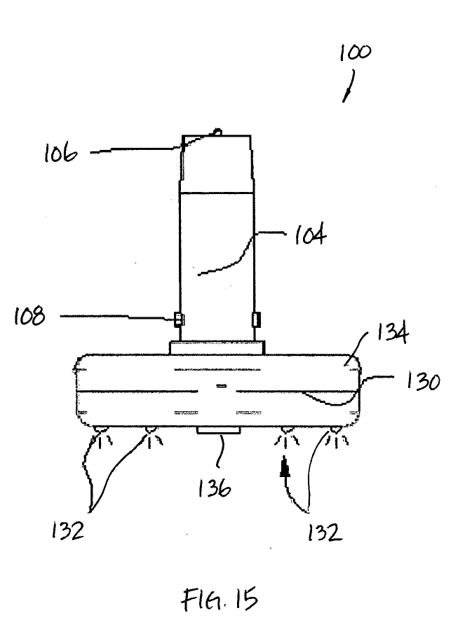

In an alternative embodiment, load device 100 includes a light source 130, as shown in FIG. 15. Light source 130 includes one or more suitable lights, such as LED lights 132, configured to emit light. LED lights 132 are positioned within a base 134 coupled to sleeve 104. A switch 136 is operatively coupled to power source 65 via conducting pin 106 and movable between a first or “on” position to supply energy to light source 130 and a second or “off” position configured to prevent energy from being supplied to light source 130.

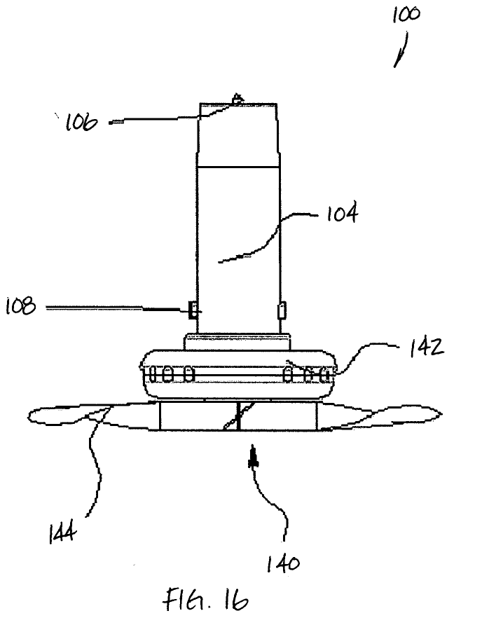

In a further alternative embodiment, load device 100 includes a fan 140, as shown in FIG. 16, rotatably coupled to a base 142. Fan 140 includes a plurality fan blades 144 configured to rotate with respect to base 142 to facilitate circulating air within interior space 39. Fan 130 may also include at least one suitable light source. A switch (not shown) is operatively coupled to power source 65 via conducting pin 106 and movable between a first or “on” position to supply energy to fan 140 and a second or “off” position configured to prevent energy from being supplied to fan 140.

In one embodiment, a method for providing energy to interior space 39 defined by collapsible structure 25 includes constructing collapsible structure 25 including hub 44 and a plurality of frame members 42 each coupled to hub 44. Frame members at least partially form a collapsible frame assembly 34 of collapsible structure 25. Solar apparatus 62 is removably coupled to hub 44. Solar apparatus 62 includes a solar panel 64 configured to absorb solar energy from the sun and a power source 65 operatively coupled to solar panel 64 and configured to convert the solar energy absorbed by solar panel 64 to electrical energy. Load device 100 is removably coupled to hub 44 and electrically coupled to solar apparatus 62. In a particular embodiment, load device 100 includes light source 102. Light source 102 includes a plurality of arms 122 movable from a collapsed configuration to an extended configuration extending radially outwardly from base 120 of light source 102. Each arm 122 includes a plurality of lights electrically coupled to power source 65 and configured to emit light.

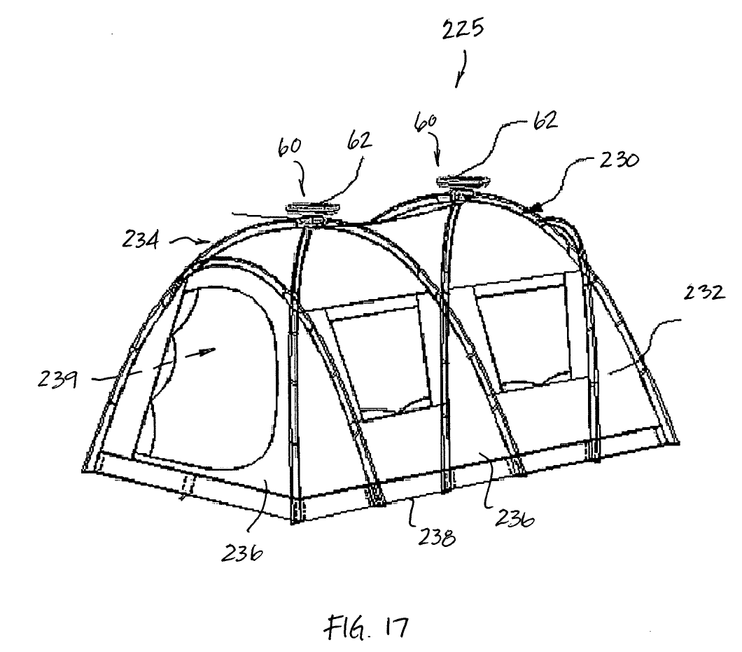

FIG. 17 shows an alternative exemplary collapsible structure 225. In this embodiment, collapsible structure 225 is a tent 230 that includes a main tent structure 232 formed of a suitable fabric material. Tent structure 232 is coupled to a collapsible frame assembly 234 to form a plurality of walls 236. A floor 238 is coupled to each wall 236 to form the collapsible structure and define an interior space 239 therein. Interior space 239 is large enough to comfortably accommodate one or more people. Collapsible structure 225 includes one or more solar power generators 60 configured to absorb solar energy and convert the solar energy to electrical energy to provide power to a load device including, without limitation, a light source; a fan or an appliance, as described above. In one embodiment, solar power generators 60 are suitable for use in cooperation with collapsible structure 225 to provide light within interior space 239, for example.

The above-described apparatus and method facilitate illuminating an interior space defined by a collapsible structure, such as a tent or a gazebo. More specifically, the apparatus and method utilize photovoltaic principles to generate electrical energy from solar power obtained from the sun. As a result, in one embodiment electrical energy in the form of light is provided in an efficient, environmentally conscience and cost-effective manner.

Exemplary embodiments of an apparatus and method for providing a light source for facilitating lighting an interior space defined by a collapsible structure are described above in detail. The apparatus and method are not limited to the specific embodiments described herein, but rather, components of the apparatus and/or steps of the method may be utilized independently and separately from other components and/or steps described herein. Further, the described apparatus components and/or method steps can also be defined in, or used in combination with, other apparatus and/or methods, and are not limited to practice with only the apparatus and method as described herein.

While the invention has been described in terms of various specific embodiments, those skilled in the art will recognize that the invention can be practiced with modification within the spirit and scope of the claims.

What is claimed is:

1. A solar power generator comprising:
a hub defining a passage;
a solar apparatus removably coupled to said hub, said solar apparatus including a solar panel configured to absorb solar energy from the sun and a power source configured to convert the solar energy absorbed by said solar panel to electrical energy; and
a load device removably coupled to said hub, said load device comprising a sleeve positioned within said passage and operatively coupling said load device to said power source, said power source configured to supply electrical energy to said load device.

2. A solar power generator in accordance with claim 1 wherein said hub further comprises:
a first locking ring formed on a first side of said hub, said first locking ring comprising a first wall, and at least one first groove defined within a radially inner surface of said first wall; and
a second locking ring formed on a second side of said hub opposing said first side, said second locking ring comprising a second wall, and at least one second groove defined within a radially inner surface of said second wall.

3. A solar power generator in accordance with claim 2 wherein said solar apparatus further comprises a locking collar defining a void and at least one first projection formed on a radially outer surface of said collar, said at least one first projection positioned within a corresponding first groove of said at least one first groove to facilitate removably coupling said solar apparatus to said hub.

4. A solar power generator in accordance with claim 3 wherein said solar apparatus further comprises a storage battery configured to store the solar energy and a socket positioned within said void, said socket electrically coupled to said storage battery.

5. A solar power generator in accordance with claim 4 wherein said sleeve further comprises:
at least one second projection formed on an outer surface of said sleeve, said at least one second projection positioned within a corresponding second groove of said at least one second groove to facilitate removably coupling said sleeve to said hub; and
a conducting pin contacting said socket with said sleeve coupled to said hub.

6. A solar power generator in accordance with claim 1 wherein said load device further comprises at least one of a light source and a fan.

7. A solar power generator in accordance with claim 1 further comprising a base coupled to said sleeve and a plurality of arms coupled to said base, each arm of said plurality of arms comprising at least one light electrically coupled to said power source.

8. A solar power generator in accordance with claim 7 wherein each said arm is pivotally coupled to said base and movable between a collapsed configuration and an extended configuration extending radially outwardly from said base.

9. A solar power generator in accordance with claim 1 wherein said load device further comprises a switch movable between a first position configured to supply energy to said load device and a second position configured to prevent energy from being supplied to said load device.

10. A solar power generator in accordance with claim 1 wherein each of said solar apparatus and said load device is rotatable with respect to said hub between a locked position and an unlocked position.

11. A collapsible structure comprising:
a hub defining a passage extending along an axis of said hub;
a plurality of frame members each coupled to said hub and at least partially forming a collapsible frame assembly;
a solar apparatus removably coupled to said hub and defining a socket aligned along said axis, said solar apparatus comprising a solar panel configured to absorb solar energy from the sun and a power source operatively coupled to said solar panel configured to convert the solar energy absorbed by said solar panel to electrical energy; and
a load device removably coupled to said hub, said load device comprising a sleeve positioned within said passage and electrically coupling said load device to said power source, said power source configured to supply electrical energy to said load device.

12. A collapsible structure in accordance with claim 11 further comprising a conducting pin coupled to a first end of said sleeve, said conducting pin positioned within said socket electrically coupling said load device to said solar apparatus.

13. A collapsible structure in accordance with claim 11 wherein said hub further comprises a first locking ring formed on a first side of said hub, and said solar apparatus further comprises a locking collar cooperating with said first locking ring to facilitate removably coupling said solar apparatus to said hub.

14. A collapsible structure in accordance with claim 13 wherein said locking collar further comprises at least one first projection formed on a radially outer surface of said locking collar, said at least one first projection positioned within a corresponding first groove defined within a radially inner surface of said first locking ring.

15. A collapsible structure in accordance with claim 13 wherein said hub further comprises a second locking ring formed on a second side of said hub opposing said first side, and said sleeve further comprises at least one second projection formed on an outer surface of said sleeve, said at least one second projection cooperating with said second locking ring to removably couple said load device to said hub.

16. A collapsible structure in accordance with claim 15 wherein said at least one first projection positioned within a corresponding second groove defined within a radially inner surface of said second locking ring.

17. A collapsible structure in accordance with claim 11 wherein said solar apparatus further comprises a storage battery configured to store the energy, said socket operatively coupled to said storage battery.

18. A collapsible structure in accordance with claim 11 wherein said load device further comprises a light source including a plurality of arms coupled to a base of said sleeve, each arm of said plurality of arms comprising a plurality of LED lights electrically coupled to said power source.

19. A collapsible structure in accordance with claim 18 wherein each said arm is pivotally coupled to said base and movable between a collapsed configuration and an extended configuration extending radially outwardly from said base.

20. A method for providing energy to an interior space defined by a collapsible structure, said method comprising:
constructing a collapsible structure including a hub and a plurality of frame members each pivotally coupled to the hub, the plurality of frame members at least partially forming a collapsible frame assembly of the collapsible structure;
removably coupling a solar apparatus to the hub, the solar apparatus comprising a solar panel configured to absorb solar energy from the sun and a power source operatively coupled to the solar panel and configured to convert the solar energy absorbed by the solar panel to electrical energy; and
removably coupling a load device to the hub, the load device electrically coupled to the solar apparatus.

21. A method in accordance with claim 20 wherein the load device further comprises a light source, said method further comprising moving a plurality of arms from a collapsed configuration to an extended configuration extending radially outwardly from a base of the light source, each arm comprising a plurality of lights electrically coupled to the power source.
